(19) United States
(12) Patent Application Publication
(10) Pub. No.: US 2007/0070756 A1
(43) Pub. Date: Mar. 29, 2007

(54) Semiconductor memory device sharing sense amplifier

(75) Inventors: Dong-Keun Kim, Kyoungki-do (KR); Chang-Ho Do, Kyoungki-do (KR)

Correspondence Address: MCDERMOTT WILL & EMERY LLP, 600 13TH STREET, N.W., WASHINGTON, DC, 20005-3096, US

(73) Assignee: Hynix Semiconductor Inc.

(21) Appl. No.: 11/478,118

(22) Filed: Jun. 30, 2006

(30) Foreign Application Priority Data
Sep. 29, 2005 (KR) 2005-0090958
Dec. 29, 2005 (KR) 2005-0133984

(51) Int. Cl. G11C 7/02

(52) U.S. Cl. 365/208

(57) ABSTRACT

A semiconductor memory device contains a reduced number of signal lines of a core area required for data access. The semiconductor memory device includes a sense amplifier for selectively sensing and amplifying data signals on a first pair of bit lines arranged at a first cell array and a second pair of bit lines arranged at a second cell array; a block selection control unit for generating a first selection control signal and a second selection control signal based on an address input for data access; and a control unit for controlling an equalization of voltage levels of the first pair of bit lines and the second pair of bit lines and for determining whether the sense amplifier is connected with the first pair of bit lines or the second pair of bit lines in response to the first selection control signal and the second selection control signal.

### FIELD OF THE INVENTION

The present invention relates to a semiconductor memory device, and more particularly to the semiconductor memory device sharing a sense amplifier.

### DESCRIPTION OF RELATED ARTS

A semiconductor memory device such as a dynamic random access memory (DRAM) typically contains a large number of memory cells in a core area. The memory cells respectively store logic data, i.e., logic high level or logic low level. Generally, in order to integrate more memory cells in the semiconductor memory device, one memory cell has only a minimum quantity of charge that can sense whether the stored logic data is high level data or low level data. Therefore, after the minimum quantity of charge of the memory cell is transferred into the data line to sense the logic high level or the logic low level, a data signal related to the minimum quantity of charge supplied at the data line must be sensed by a sensor and amplified by an amplifier for a data access operation. The semiconductor memory device typically contains a sense amplifier for sensing and amplifying a data signal supplied to the data line, i.e., a bit line.

A plurality of word lines and a plurality of bit lines intersect in the core area of the semiconductor memory device. The memory cells are arranged at a plurality of intersection points of the word lines and the bit lines. The memory cells are grouped by blocks that form a cell array. A selected plurality of bit lines and a selected plurality of word lines are arranged at one cell array for accessing data of memory cells in the selected cell array. A plurality of sense amplifiers corresponding to the selected plurality of bit lines in the cell array are set at one side of the cell array.

For reducing the core area of the semiconductor memory device, two neighbored cell blocks can share one sense amplifier. That is, a sense amplifier can sense and amplify a data signal supplied at a bit line of one neighbored cell block or another data signal supplied at another bit line of the other neighbored cell block. In this configuration, the semiconductor memory device shares a sense amplifier.

FIG. 1 is a block diagram of a core area and a control signal generating unit of a conventional semiconductor memory device.

The core area 300 includes a plurality of cell arrays, e.g., 310A, 310B, 310C, 340A, 340B and 340C and a plurality of sense amplifying units, e.g., 320A, 320B and 320C, each corresponding, respectively, to two cell arrays, e.g., 310A and 340A, 310B and 340B, and 310C and 340C.

Sub word line decoders 330A, 330B, 330C, 350A, 350B and 350C are respectively arranged at spaces between two corresponding cell arrays. Transferring units, e.g., 360A, 360B, 360C are respectively arranged at spaces called sub-hole regions between corresponding two adjacent sense amplifying units among the plurality of sense amplifying units, e.g., 320A, 320B and 320C and so on. The transferring units 360A, 360B and 360C are circuits for transferring an equalizing control signal BLEQb and connecting control signals BISHb and BISLb from the control signal generating unit 200 into the sense amplifying units 320A, 320B and 320C.

The control signal generating unit 200 includes a block selection signal generating unit 210, a connection signal generating unit 220 and an equalizing signal generating unit 230. The block selection signal generating unit 210 generates block selection signals BS_0 and BS_1 in response to addresses BAX input for a cell block selection. The connection signal generating unit 220 generates the connecting control signals BISHb and BISLb and the equalizing signal generating unit 230 generates an equalizing signal BLEQb in response to the block selection signals BS_0 and BS_1. The block selection signal generating unit 210 includes a first selection signal generating unit 212 for generating the block selection signal BS_0 and a second selection signal generating unit 214 for generating the block selection signal BS_1.

The control signals BISHb, BISLb and BLEQb are transferred into the core area 300 through metal lines M1, M2 and M3, respectively. In the core area, the transferring units transfer the control signals supplied though the metal lines M1, M2 and M3 into the sense amplifying units. In detail, outputs of the transferring units 360A, 360B and 360C are transferred into gates of MOS transistors of respective connecting units and equalizing units in the sense amplifying units.

FIG. 2 is a schematic diagram of a data transferring unit in FIG. 1.

The transferring unit, e.g., 360A includes an inverter 21 for inverting the connecting control signal BISLb to output a connection control signal BISL, an inverter 22 for inverting the equalizing control signal BLEQb to output a equalization control signal BLEQ and an inverter 23 for inverting the connecting control signal BISHb to output a connection control signal BISH.

As described above, the connecting signal generating unit 220 generates the connecting control signals BISHb and BISLb and the equalizing signal generating unit 230 generates the equalizing control signal BLEQb. There are many metal lines M1, M2 and M3 for transferring the control signals BISHb, BISLb and BLEQb from the control signal generating unit 200 into the sense amplifying units.

Generally, the metal lines M1, M2 and M3 for supplying the control signals BISHb, BISLb and BLEQb and other metal lines for supplying power voltages, ground voltages, etc are arranged in a predetermined area of the core area.

Therefore, as described above, since there are many lines for transferring the many control signals into the core area, it is very difficult to arrange many metal lines in the core area.

### SUMMARY OF THE INVENTION

It is, therefore, an object of the present invention to provide various embodiments for a semiconductor memory device capable of reducing signal lines in a core area.

In accordance with an aspect of the present invention, there is provided a semiconductor memory device, including: a sense amplifier for selectively sensing and amplifying data signals on a first pair of bit lines arranged at a first cell array and a second pair of bit lines arranged at a second cell array; a block selection control unit for generating a first selection control signal and a second selection control signal based on an address input for data access; and a control unit for controlling an equalization of voltage levels of the first pair of bit lines and the second pair of bit lines and for determining whether the sense amplifier is connected with the first pair of bit lines or the second pair of bit lines in response to the first selection control signal and the second selection control signal.

In accordance with another aspect of the present invention, there is provided a method for operating a semiconductor memory device with a sense amplifier shared by a first cell array with a second cell array, including: generating a first selecting control signal and a second selecting control signal corresponding to the first cell array and the second cell array, respectively, in response to an address inputinput for data access; controlling the equalization of voltage levels of first pair of bit lines arranged at the first cell array and second first pair of bit lines arranged at the second cell array in response to the first selection control signal and the second selection control signal; and controlling whether the sense amplifier is connected with the first pair of bit lines or the second pair of bit lines in response to the first selection control signal and the second selection control signal.

In accordance with another aspect of the present invention, there is provided a semiconductor memory device, including: a sense amplifier for selectively sensing and amplifying data signals on a first pair of bit lines arranged at a first cell array and a second pair of bit lines arranged at a second cell array; a block selection control unit for generating a first selection control signal and a second selection control signal based on an address input for data access; and a repeater for controlling connection of the first pair of bit lines or the second pair of bit lines in response to the first selection control signal and the second selection control signal.

### BRIEF DESCRIPTION OF THE DRAWINGS

The above and other objects and features of the present invention will become apparent from the following description of preferred embodiments taken in conjunction with the accompanying drawings, in which:

FIG. 1 shows a block diagram of a core area of a conventional semiconductor memory device;

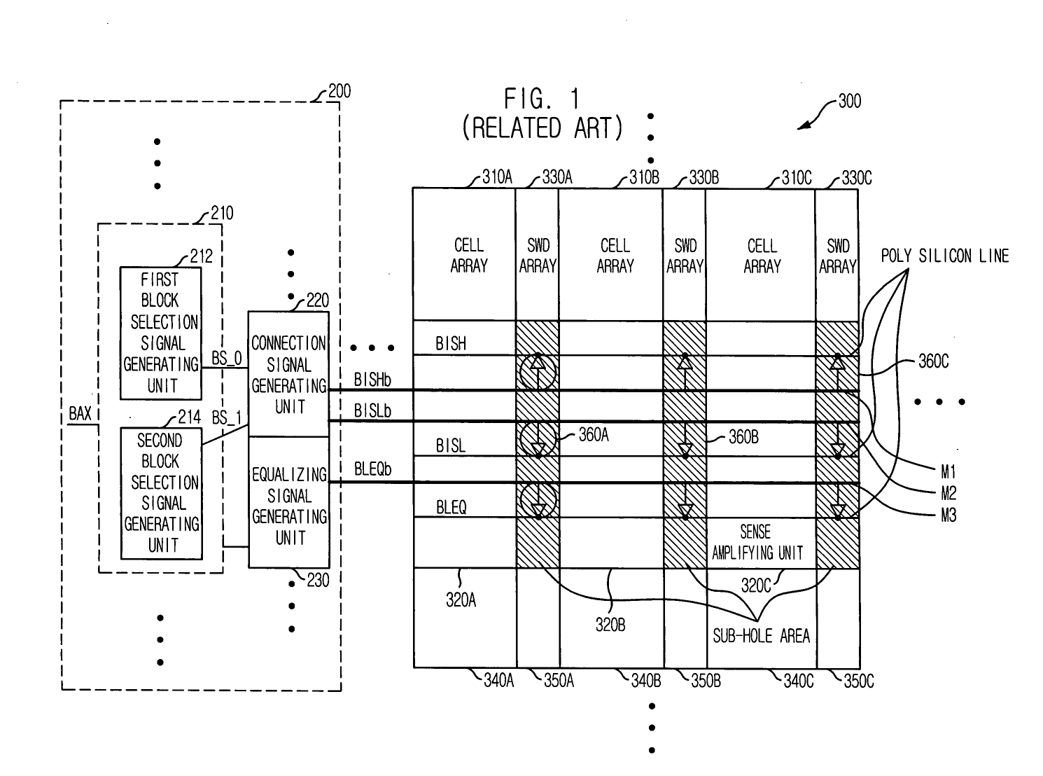

FIG. 2 shows a schematic diagram of a data transferring unit in FIG. 1;

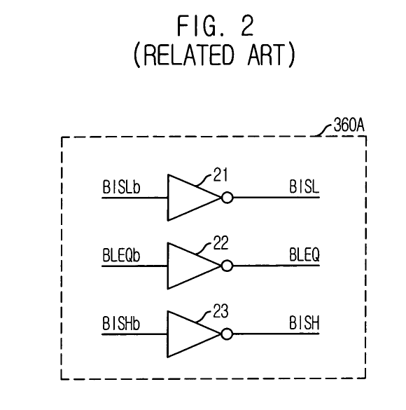

FIG. 3 shows a block diagram of a core area of the semiconductor memory device in accordance with an embodiment of the present invention;

FIG. 4 shows a schematic diagram of a control unit in FIG. 3; and

FIG. 5 shows a schematic diagram of a sense amplifying unit in FIG. 3.

### DETAILED DESCRIPTION OF THE INVENTION

Hereinafter, a semiconductor memory device in accordance with the present invention will be described in detail referring to the accompanying drawings.

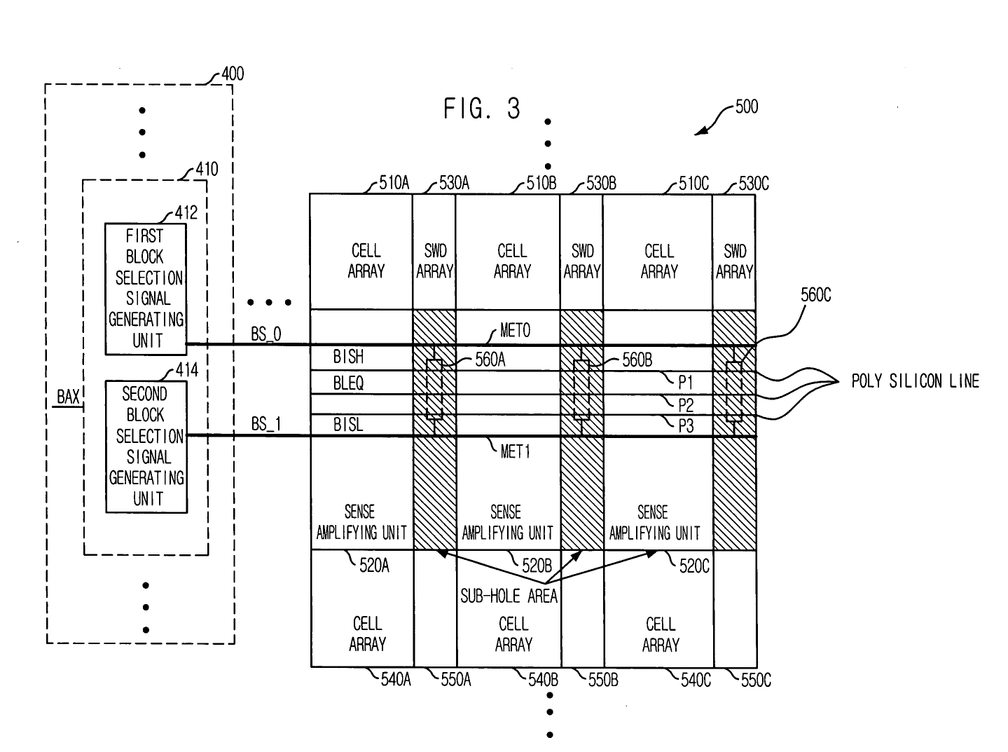

FIG. 3 shows a block diagram of a core area of the semiconductor memory device in accordance with an embodiment of the present invention.

The core area 500 includes a plurality of cell arrays, e.g., 510A, 510B, 510C, 540A, 540B and 540C and a plurality of sense amplifying units 520A, 520B, 520C, . . . respectively corresponded with two cell arrays.

Memory cells are respectively arranged at cell arrays, e.g., 510A, 510B, 510C, 540A, 540B and 540C. The sense amplifying units, e.g., 520A, 520B and 520C respectively includes a sense amplifier for sensing and amplifying a first pair of bit lines arranged at a first cell array, e.g., cell array 510A or a second pair of bit lines arranged at a second cell array, e.g., cell array 540A.

Sub word line decoders, e.g., 530A, 530B, 530C, 550A, 550B and 550C are arranged at spaces between the cell arrays, e.g., 510A, 510B, 510C, 540A, 540B and 540C. The sub word line decoders decode addresses input for data access. One of sub word lines arranged at a selected cell array is selected by the decoded result.

Control units, e.g., 560A, 560B and 560C are arranged at spaces, in a so-called sub-hole area, between the sense amplifying units, e.g., 520A, 520B and 520C. Hereinafter, because all the control units, e.g., 560A, 560B and 560C perform substantially the same operation, the operation of the control unit will be described referring to the control unit 560A.

The control unit 560A controls an equalizing operation of the first pair of bit lines in the first cell array 510A and the second first pair of bit lines in the second cell array 540A. Also, the control unit 560A controls whether the sense amplifier (not shown) of the sense amplifying units 520A is connected with the first pair of bit lines in the first cell array 510A or the second pair of bit lines in the second cell array 540A in response to the first selection control signal BS_0 and the second selection control signal BS_1. The other control units 550B, 560C, . . . perform substantially the same operation as the control unit 560A.

The block selection control unit 400 generates the first selection control signal BS_0 and the second selection signal BS_1 corresponding to the address signal BAX input and decoded for data access. The block selection control unit 400, is arranged at a space arranged for decoding the address in the semiconductor.

The first selection control signal BS_0 and the second selection signal BS_1 are transferred through transferring lines MET0 and MET1. That is, first and second transferring lines MET0 and MET1 respectively transfer the first selection control signal BS_0 and the second selection control signal BS_1 from the block selection control unit 400 into the control units 560A, 560B, . . . The first and second transferring lines MET0 and MET1 are made of metal. Also, a third and a fourth transferring lines P1 and P2 respectively transfers a first connecting control signal BISH and a second connecting control signal BISL from the control units 560A and 560B into the sense amplifying units, e.g., 520A, 520B and 520C. Through a fifth transferring line P3, the equalizing control signal BLEQ is transferred from the control unit 560A and 560B into the sense amplifying units, e.g., 520A, 520B and 520C. The third to fifth transferring lines P1, P2 and P3 are made of poly silicon line.

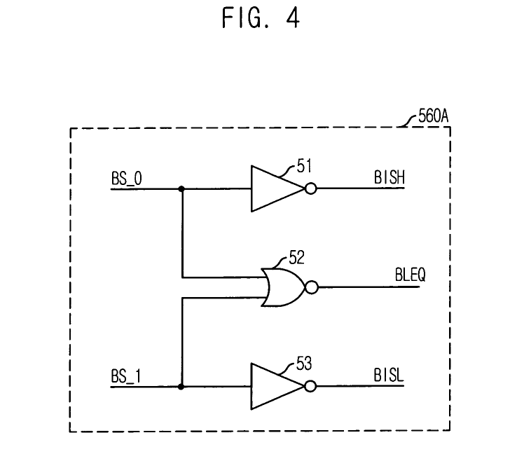

FIG. 4 is a schematic diagram of a control unit in FIG. 4.

The control unit 560A includes a first inverter 51, a second inverter 53 and a logic unit 52. The first inverter 51 inverts the first selection control signal BS_0 to generate the first connecting control signal BISH for connecting the sense amplifier of the sensing amplifier 520A with the first pair of bit lines arranged in the cell array 510A.

The second inverter 53 inverts the second selection control signal BS_1 to generate the second connecting control signal BISL for connecting the sense amplifier of the sensing amplifier 520A with the second pair of bit lines arranged in the cell array 540A.

The logic unit 52 generates the equalizing control signal BLEQ to equalize potential levels of the first pair of bit lines in the cell array 510A or the second pair of bit lines arranged in the cell array 540A using the first selection control signal BS_0 and the second selection control signal BS_1. The logic unit 52 is a NOR logical gate.

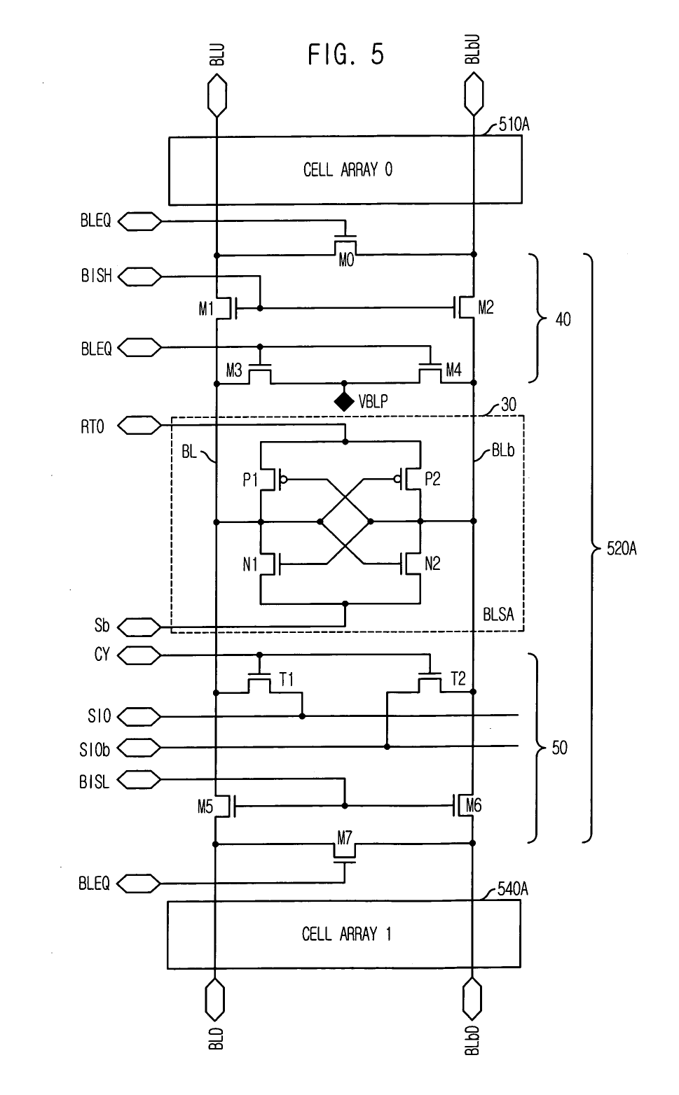

FIG. 5 is a schematic diagram of a sense amplifying unit in FIG. 3.

The sense amplifying unit 520A is located between the first cell array 510A and the second cell array 540A and shared by the first cell array 510A and the second cell array 540A. The sense amplifying unit 520A includes a sense amplifier 30, a first circuit unit 40 between the sense amplifier 30 and the first cell array 510A and a second circuit unit 50 between the sense amplifier 30 and the second cell array 540A.

The sense amplifier 30 includes a PMOS transistor P1 between a bit line BL and a first power supplying line RTO for amplifying as a logic high level of data signal, a PMOS transistor P2 between a bit line BLb and the first power supplying line RTO, an NMOS transistor N1 between a bit line BL and a second power supplying line Sb for amplifying as a logic low level of data signal and an NMOS transistor N2 between a bit line BLb and a second power supplying line Sb.

The first circuit unit 40 includes a first equalizing unit having an NMOS transistor M0, a connecting unit having NMOS transistors M1 and M2, and a precharging unit having NMOS transistors M3 and M4.

The NMOS transistor M0 equalizes two potential levels of the bit lines BLU and BLbU of the first cell array 510A in response to an equalizing control signal BLEQ. The NMOS transistors M1 and M2 of the first connecting unit respectively connect or isolate the bit lines BL and BLb connected to the sense amplifier 30 with the bit lines BLU and BLUb of the first cell array 510A in response to a connecting control signal BISH. The NMOS transistors M3 and M4 of the precharging unit respectively transfer the precharge voltage into the bit lines BL and BLb connected to the sense amplifier 30 for a precharging operation in response to the equalizing control signal BLEQ.

The second circuit unit 50 includes a second equalizing unit having an NMOS transistor M7, a connecting unit having NMOS transistors M5 and M6, and a data output unit having NMOS transistors T1 and T2.

The NMOS transistor M7 equalizes two potential levels of the bit lines BLD and BLbD of the second cell array 540A in response to an equalizing control signal BLEQ. The NMOS transistors M5 and M6 of the second connecting unit respectively connect or isolate the bit lines BL and BLb connected to the sense amplifier 30 with the bit lines BLD and BLbD of the second cell array 540A in response to the connecting control signal BISL. The NMOS transistors T1 and T2 of the data output unit respectively transfers data signals supplied at the bit lines BL and BLb into data output lines SIO and SIOb in response to a decoded column signal CY.

In conclusion, as described above, the sense amplifier 30 is shared by the first cell array 510A and the second cell array 540A.

Hereinafter, an operation of the semiconductor memory device in accordance with the embodiment of the present invention will be described referring to FIG. 3 to FIG. 5.

At a ready state for data access, i.e., a precharge mode, the block selection signals BS_0 and BS_1 are activated as the logic low level. Then, the first and second connecting control signals BISH and BISL and the equalizing control signal BLEQ are activated as the logic high level. The MOS transistors M1 to M7 are turned on in response to the activated control signals BLEQ, BISH and BISL.

At first, in case of selecting the cell array 510A by the input address, after an active command and an address are input for data access, the block selection control unit 400 maintains the first selection control signal BS_0 as the logic low level and generates the second selection control signal BS_1 inactivated as the logic high level.

The control unit 560A maintains the first connecting control signal BISH as the logic high level, and generates the equalizing control signal BLEQ and the second connecting control signal BISL inactivated as the logic low level. Therefore, the NMOS transistors M1 and M2 are are turned on and the NMOS transistors M0, M3 to M7 are turned off. The bit lines BL and BLb connected to the sense amplifier 30 are coupled to the bit lines BLU and BLbU of the second cell array 510A. The bit lines BL and BLb are isolated from the bit lines BLD and BLbD of the first cell array 540A. That is, the sense amplifier 30 is coupled to the second cell array 510A. Then, the sense amplifier 30 senses and amplifies data signals supplied at the bit lines BLU and BLbU of the second cell array 510A.

In selecting the cell array 540A by the input address, the block selection control unit 400 generates the first selection control signal BS_0 activated as logic high level and the second selection control signal BS_1 as logic low level after the active command and the address is input for data access.

The control unit 560A maintains the second connecting control signal BISL as the logic high level and generates the equalizing control signal BLEQ and the first connecting control signal BISH as the logic low level. Therefore, the NMOS transistors M5 and M6 are turned on and the NMOS transistors M0 to M4 and M7 are turned off. The bit lines BL and BLb connected to the sense amplifier 30 are coupled to the bit lines BLD and BLbD of the first cell array 540A. The bit lines BL and BLb are isolated from the bit lines BLU and BLbU of the second cell array 510A. That is, the sense amplifier 30 is coupled to the second cell array 540A. Then, the sense amplifier 30 senses and amplifies signals supplied at the bit lines BLD and BLbD of the second cell array 540A.

As described above, the semiconductor memory device in accordance with the first embodiment of the present invention controls the equalizing operation of potential levels of the bit lines arranged at the first cell array 510A and the second cell array 540A and controls whether the sense amplifier is connected to the first cell array 510A or the second cell array 540A using the first selection control signal BS_0 and the second selection control signal BS_1.

That is possible because the first and the second selection control signals BS_0 BS_1 are transferred directly into the control unit 560A of the core area 500 through the first and second transferring lines MET0 and MET1. In addition, the first and second connecting control signals BISH and BISL and the equalizing control signal BLEQ are transferred from the control unit 560A into the amplifying unit 560A through the poly silicon line.

Therefore, control signal lines for controlling the amplifying unit 560A can be reduced. In detail, referring to two cell arrays, the signal lines can be reduced from three lines, i.e., BISH, BLEQ and BISL into two lines, i.e., BS_0 and BS_1. As a result, it is possible to reduce a circuit area for arranging power lines, i.e., lines for providing power supply voltage or ground voltage to control the amplifying units.

Although the semiconductor memory is described by example above, it is possible to use various alternatives, modifications and equivalents. For example, those skilled in the art would appreciate that the control scheme described in connection with FIG. 4 can be employed in the context of any type of logical circuit.

The present application contains subject matter related to Korean patent application No. 2005-90958 and 2005-133984 filed in the Korea Patent Office on Sep. 29, 2005 and Dec. 29, 2005, respectively, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. A semiconductor memory device, comprising:
a sense amplifier for selectively sensing and amplifying data signals on a first pair of bit lines arranged at a first cell array and a second pair of bit lines arranged at a second cell array;
a block selection control unit for generating a first selection control signal and a second selection control signal based on an address input for data access; and
a control unit for controlling an equalization of voltage levels of the first pair of bit lines and the second pair of bit lines and for determining whether the sense amplifier is connected with the first pair of bit lines or the second pair of bit lines in response to the first selection control signal and the second selection control signal.

2. The semiconductor memory device of claim 1 wherein the control unit includes:
a first inverter for inverting the first selection control signal to generate a first connecting control signal for connecting the sense amplifier with the first pair of bit lines;
a second inverter for inverting the second selection control signal to generate a second connecting control signal for connecting the sense amplifier with the second pair of bit lines; and
a logic unit for generating an equalizing control signal in response to the first selection control signal and the second selection control signal to selectively equalize the first pair of bit lines and the second pair of bit lines.

3. The semiconductor memory device of claim 2 wherein the control unit is arranged at a space between the sense amplifier unit and another sense amplifier adjacent to the sense amplifier.

4. The semiconductor memory device of claim 3 wherein the block selection control unit is arranged at a region where the address is decoded.

5. The semiconductor memory device of claim 4 further comprising:
a first and a second transferring lines for respectively transferring the first selection control signal and the second selection control signal from the block selection control unit to the control unit;
a third and a fourth transferring lines for respectively transferring the first connecting control signal and the second connecting control signal from the control unit to the sense amplifying units; and
a fifth transferring line for transferring the equalizing control signal from the control unit to the sense amplifying units.

6. The semiconductor memory device of claim 5 wherein the first and second transferring lines are made of metal.

7. The semiconductor memory device of claim 6 wherein the third to fifth transferring lines are made of poly silicon.

8. A method for operating a semiconductor memory device having a sense amplifier shared by a first cell array and a second cell array, the method comprising:
generating a first selecting control signal and a second selecting control signal corresponding to the first cell array and the second cell array, respectively, in response to an address input for data access;
controlling the equalization of voltage levels of first pair of bit lines arranged at the first cell array and second first pair of bit lines arranged at the second cell array in response to the first selection control signal and the second selection control signal; and
controlling whether the sense amplifier is connected with the first pair of bit lines or the second pair of bit lines in response to the first selection control signal and the second selection control signal.

9. The method of claim 8 wherein controlling the equalization includes:
performing a NOR logic operation of the first selection control signal and the second selection control signal to generate an equalization control signal for the equalization.

10. The method of claim 9 wherein controlling whether the sense amplifier is connected with the first pair of bit lines or the second pair of bit lines includes:
inverting the first selection control signal to generate a first connecting control signal for connecting or isolating the sense amplifier with the first pair of bit lines; and
inverting the second selection control signal to generate a second connecting control signal for connecting or isolating the sense amplifier with the second pair of bit lines.

11. A semiconductor memory device, comprising:
a sense amplifier for selectively sensing and amplifying data signals on a first pair of bit lines arranged at a first cell array and a second pair of bit lines arranged at a second cell array;
a block selection control unit for generating a first selection control signal and a second selection control signal based on an address input for data access; and
a repeater for controlling connection of the first pair of bit lines or the second pair of bit lines in response to the first selection control signal and the second selection control signal.

12. The semiconductor memory device of claim 11 wherein the control unit includes:
a first driver for driving the first selection control signal to generate a first connecting control signal for connecting the sense amplifier with the first pair of bit lines;
a second driver for driving the second selection control signal to generate a second connecting control signal for connecting the sense amplifier with the second pair of bit lines; and
a third driver for generating an equalizing control signal in response to the first selection control signal and the second selection control signal to selectively equalize the first pair of bit lines and the second pair of bit lines.

13. The semiconductor memory device of claim 12 wherein the control unit is arranged at a space between the sense amplifier unit and another sense amplifier adjacent to the sense amplifier.

14. The semiconductor memory device of claim 13 wherein the block selection control unit is arranged at a region where the address is decoded.

15. The semiconductor memory device of claim 14 further comprising:
a first and a second transferring lines for respectively transferring the first selection control signal and the second selection control signal from the block selection control unit to the control unit;
a third and a fourth transferring lines for respectively transferring the first connecting control signal and the second connecting control signal from the control unit to the sense amplifying units; and
a fifth transferring line for transferring the equalizing control signal from the control unit to the sense amplifying units.

16. The semiconductor memory device of claim 15 wherein the first and second transferring lines are made of metal.

17. The semiconductor memory device of claim 16 wherein the third to fifth transferring lines are made of poly silicon.
